(19) United States
(12) Patent Application Publication
(10) Pub. No.: US 2005/0174877 A1
(43) Pub. Date: Aug. 11, 2005

(54) Bus arrangement and method thereof

(76) Inventors: Soon-Jae Cho, Suwon-si (KR); Woo-Young Jang, Seoul (KR); Chae-Eun Rhee, Suwon-si (KR)

Correspondence Address: HARNESS, DICKEY & PIERCE, P.L.C., P.O. BOX 8910, RESTON, VA, 20195, US

(21) Appl. No.: 11/037,076

(22) Filed: Jan. 19, 2005

(30) Foreign Application Priority Data
Feb. 6, 2004 (KR) 2004-08053

(51) Int. Cl. G11C 8/02

(52) U.S. Cl. 365/232

(57) ABSTRACT

A bus arrangement is provided including a master device and a slave device. A master converts a read command into a write command and sends the write command through a bus network within the bus arrangement and a slave device converts the write command back to the read command and sends a response. The response is sent on a bus not included within the bus network, thereby reducing a response delay time between the transmission of the read command and the response to the read command.

### CROSS-REFERENCE TO RELATED APPLICATIONS

This U.S. non-provisional patent application claims priority under 35 U.S.C. § 119 of Korean Patent Application 2004-08053 filed on Feb. 6, 2004, the entire contents of which are hereby incorporated by reference.

### BACKGROUND OF THE INVENTION

1. Field of the Invention

The present invention relates generally to a bus arrangement and method thereof, and more particularly to a bus arrangement including a reduced response time and method thereof.

2. Description of the Related Art

A system-on-chip (SOC) may be highly integrated and/or difficult to fabricate by conventional methods. Thus, it may be difficult to deliver a SOC to a market in a reasonable period of time. SOCs may be designed based on a platform in order to reduce a time-to-market. The devices included in the SOC may share a system memory through a bus system. The devices in the SOC may be connected to the bus system, and the bus system may transfer data between the connected devices. Since the bus system is shared by the devices, the bandwidth of the bus system (i.e., an amount of data that may be transferred over the bus system at a given time) may limit data transmission between the devices. Thus, a conventional SOC may have a reduced data transmission capacity due to the limit on bus system bandwidth. In other words, the connected devices may access a memory on the bus system such that the bus system traffic (i.e., an amount of data transferred over the bus system) may increase. The performance of the SOC may degrade as the bus system traffic increases since the bus system bandwidth may be limited.

FIG. 1 illustrates a network 50 according to conventional methods.

The network 50 may include IP cores 10-18 (e.g., masters, slaves, etc.) and agents 20-28.

Referring to FIG. 1, each of IP cores 10-18 may communicate with corresponding agents 20-28 through an open core protocol (OCP) interface. The agents 20-28 may each correspond to the IP cores 10-18, respectively (i.e., agent 20 may be connected to IP Core 10, agent 21 may be connected to IP Core 11, etc. . . . ). The agents 20-28 may communicate (i.e., transfer data) with each other through a network (i.e., bus system) including silicon backplane (SB) protocols.

FIG. 2 illustrates an operational timing diagram of components in FIG. 1 when IP Core 10 (i.e., a CPU controller) reads data stored in IP Core 15 (i.e., a memory device).

Referring to FIG. 2, when the IP Core 10 generates the read command, a data address associated with the read command may be transmitted to an agent 20. The agent 20 (i.e., an initiator agent) may arbitrate an access to a network 30. The read command and the data address may be sent to the agent 25 (i.e., a target agent) based on the arbitration of the agent 20. Read data and a response signal may be transmitted from the memory 15 to the agent 20 through the agent 25. The agent 20 may send the read data and response signal to the IP Core 10.

Referring again to FIG. 2, an arbitration time and a slave processing time (i.e., delay times) may be required before a response signal Resp1 may be generated after the read command is generated and transmitted. Further, if the read command is a burst read command, the agent 20 may need to arbitrate by units of bursts. When a plurality of masters access the network 30 at the same time to request data, an increased amount of time may be required to transmit the entire read data to the IP Core 10 due at least to the above-described delays.

A conventional network (e.g., a micro-network, a silicon backplane μ Network, etc. . . . ) may include a ring and/or tree type structure, which may allocate resources (i.e., bandwidth) and may increase routing efficiency. However, similar to above-described deficiencies with regard to simultaneous data requests, the response delay time with respect to each master in the conventional network may be increased when a plurality of masters access a network (e.g., network 30) simultaneously to request data.

### SUMMARY OF THE INVENTION

An exemplary embodiment of the present invention is a bus arrangement, including a bus network connecting a master device and a slave device, and a response decoder receiving a response signal from the slave device, the response signal received on a first bus not included within the bus network.

Another exemplary embodiment of the present invention is a bus arrangement, including a bus network connecting a plurality of master devices and a plurality of slave devices, a plurality of buses connecting a response decoder and the plurality of master devices, the plurality of buses not included within the bus network, the response decoder receiving a response signal from at least one of the plurality of slave devices and transmitting the response signal to at least one of the plurality of master devices.

Another exemplary embodiment of the present invention is a method of reading data in a bus arrangement, including generating a read command at a master devise, converting the read command to a write command, transmitting the converted write command to a slave device through a bus network, and transmitting data read from the slave device in response to the write command to the master device through a bus not included within the bus network.

Another exemplary embodiment of the present invention is a bus arrangement, including a slave device and a master device connected through a bus network, and a bus connecting the slave device and the master device, the bus not included within the bus network.

Another exemplary embodiment of the present invention is a method of reading data, including generating a read command at a first device, and converting the read command into a write command.

Another exemplary embodiment of the present invention is a method of data transfer, including receiving a write command through a bus network, and performing a read operation in response to the write command.

Another exemplary embodiment of the present invention is a method of data transfer, including transmitting a write command through a bus network, and receiving data in response to the write command through a bus, the bus not included within the bus network.

Another exemplary embodiment of the present invention is a master device, including a first connection to a slave device through a bus network, and a second connection to the slave device, the second connection not included within the bus network.

Another exemplary embodiment of the present invention is a slave device, including a first connection to a master device through a bus network, and a second connection to the master device, the second connection not included within the bus network.

### BRIEF DESCRIPTION OF THE DRAWINGS

The present invention will become more apparent by describing in detail exemplary embodiments thereof with reference to the attached drawings in which:

FIG. 1 illustrates a network according to conventional methods.

FIG. 2 illustrates an operational timing timing diagram of components in FIG. 1 when an IP Core reads data stored in another IP Core.

FIG. 3 illustrates a block diagram of a bus arrangement according to an exemplary embodiment of the present invention.

FIG. 4 illustrates a flow chart showing a data read execution according to another exemplary embodiment of the present invention.

FIG. 5 illustrates a time delay between a generated read command from a master device and response signals for the bus arrangement of FIG. 3.

FIG. 6 illustrates a bus arrangement according to another exemplary embodiment of the present invention.

### DETAILED DESCRIPTION OF EXEMPLARY EMBODIMENTS OF THE PRESENT INVENTION

Hereinafter, exemplary embodiments of the present invention will be described in detail with reference to the accompanying drawings.

In the Figures, the same reference numerals are used to denote the same elements throughout the drawings.

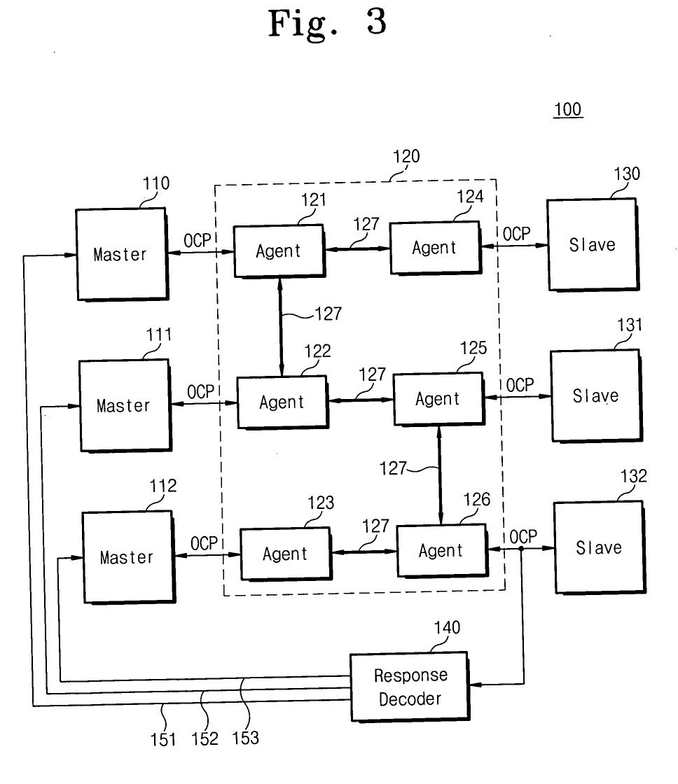

FIG. 3 illustrates a block diagram of a bus arrangement 100 according to an exemplary embodiment of the present invention. As shown in FIG. 3, the bus arrangement 100 may include master devices 110/111/112 and slave devices 130/131/132.

In another exemplary embodiment of the present invention, the master devices 110/111/112 and slave devices 130/131/132 may communicate (i.e. transfer data or information) through a network 120, such as a Silicon Backplane (SB) μ Network.

In another exemplary embodiment of the present invention, referring to FIG. 3, the master devices 110/111/112 may include, but need not be limited to, Central Processing Units (CPUs), Hard Disk Drive (HDD) controllers, audio and/or video Digital Signal Processors (DSPs) and/or Moving Picture Expert Group (MPEG) processors.

In another exemplary embodiment of the present invention, referring to FIG. 3, the slave devices 130/131/132 may include, but need not limited to, input/output (I/O) devices, and/or memory devices.

In another exemplary embodiment of the present invention, a number of master devices and/or slave devices that are connected to the network 120 may be changed based on system requirements.

In another exemplary embodiment of the present invention, the network 120 may include agents 121-126. The agents 121-126 may each correspond to at least one of the master devices 110/111/112 and/or the slave devices 130/131/132. The communications (i.e., data transfers) between the master devices 110/111/112 and the agents 121-123 and the slave devices 130/131/132 and the agents 124-126 may be based on an open core protocol (OCP) interface. The adjoining agents (i.e., agents with a connection to other agents) may be connected to each other via a bus 127, such as a SB bus.

In another exemplary embodiment of the present invention, the network 120 may include a ring and/or tree shape structure. This structure may allocate resources (i.e., bandwidth) and/or may increase routing efficiency.

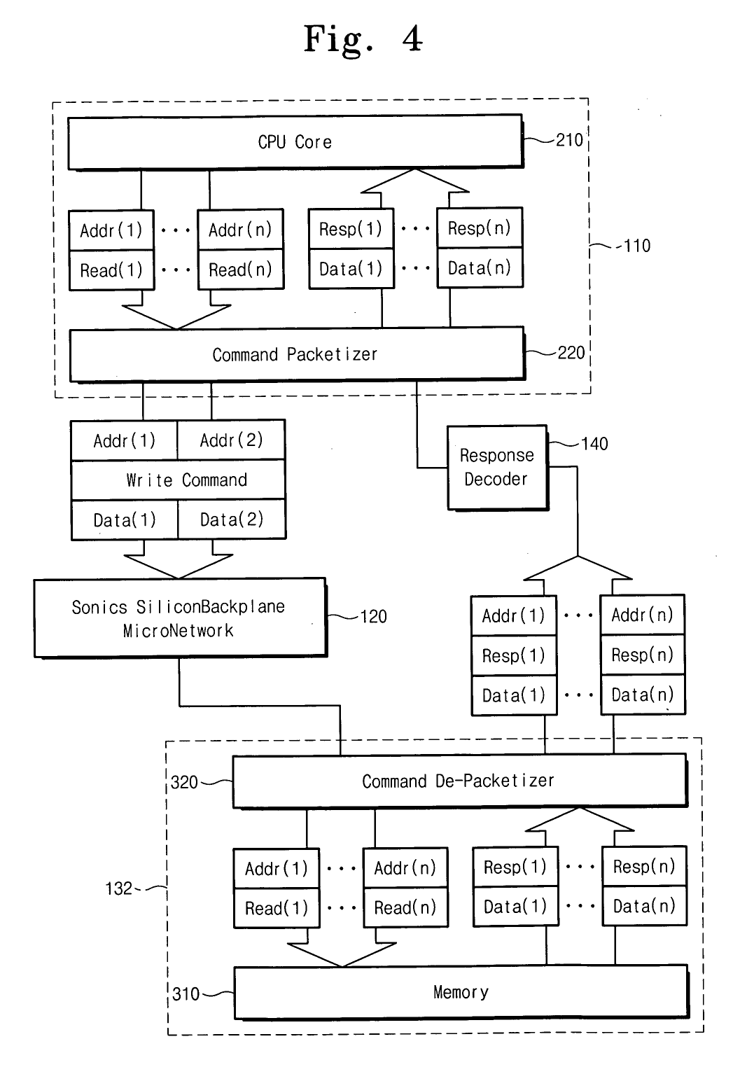

FIG. 4 illustrates a flow chart showing a data read execution according to another exemplary embodiment of the present invention.

In another exemplary embodiment of the present invention, referring to FIG. 4, the master device 110 (i.e., IP core) may include a CPU core 210 and/or a command packetizer 220.

In another exemplary embodiment of the present invention, referring to FIG. 4, a read command Read (e.g., a burst read command, a normal read command, etc. . . . ) and an address Addr may be sent to the command packetizer 220.

In another exemplary embodiment of the present invention, a series of burst read commands Read(1) . . . Read(n) and addresses Addr(1) . . . Addr(n) may be sent to the command packetizer 220.

In another exemplary embodiment of the present invention, the command packetizer 220 may convert the read command Read to a write command and may packetize the converted write command (e.g., include the write command in a packet for transmission) and data (e.g., the address a write command treats as data) to transmit through the network 120.

In another exemplary embodiment of the present invention, the command packetizer 220 may reduce a response time (e.g., delays incurred by consecutive read commands) by converting the read command Read into the write command (e.g., a response time from the memory device 132 may be reduced). The data Data(1) . . . Data(n) may be invalid (i.e., null and/or garbage) data since the data associated with the converted write command may be irrelevant.

In another exemplary embodiment of the present invention, the memory device 132 may include a memory 310 and/or a command depacketizer 320.

In another exemplary embodiment of the present invention, the converted write command, the address and the data may be sent to the command depacketizer 320 through the network 120. The command depacketizer 320 may restore (i.e., convert) the write command back to the read command, and the restored read command and the address may be transmitted to the memory 310. The memory 310 may output the data 1-N stored in the received address 1-N (i.e., data 1 being associated with data stored in address 1 of the memory 310, and so on) and a response signal Resp 1-N to the command depacketizer 320.

In another exemplary embodiment of the present invention, the command depacketizer 320 may include the address Addr 1-N with the data 1-N (i.e., the data received from the address Addr of memory 310) and the response signal Resp 1-N from the memory 310 and may transmit the data 1-N, address Addr 1-N and the response signal Resp 1-N to a response decoder 140. The address Addr 1-N received by the response decoder 140 may include information for requesting an operation (e.g., data requested by the master device through a read command).

In another exemplary embodiment of the present invention, the response decoder 140 may transmit the response signal Resp and the data to the master device 110 based on the address Addr received from the command depacketizer 320 of the slave device 132 (e.g., a memory device).

In another exemplary embodiment of the present invention, referring to FIG. 3, the response decoder 140 may be connected to each of the master devices 110/111/112 through buses 151/152/153, respectively. Therefore, the response signal Resp and the data received at the response decoder 140 from the slave device 132 may be transferred directly to the master device (e.g., one of master devices 110/111/112). While FIG. 3 illustrates slave device 132 being connected to the response decoder 140, it is understood that any slave device including a memory (e.g., slave device 130, 131, etc. . . . ) may output to the response decoder 140.

In another exemplary embodiment of the present invention, the bus arrangement 100 may transmit requested data to one of the master devices 110/111/112 through a bus not included within the network 120. Thus, a response time between sending a read command from a master device and receiving the read data from a slave device (e.g., a memory device) may be reduced.

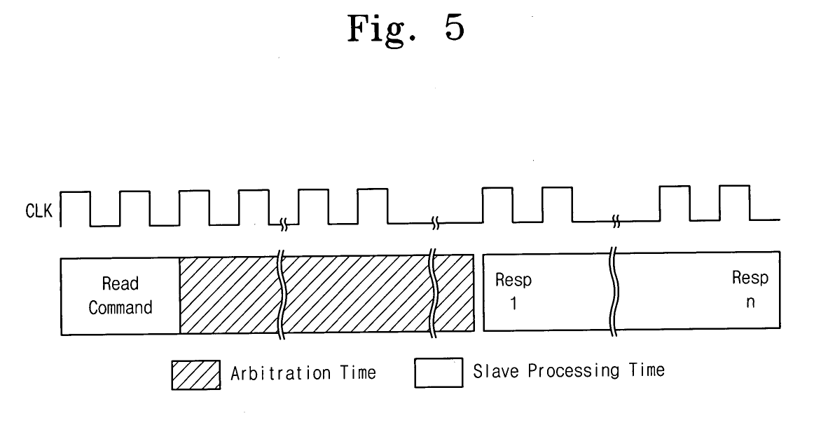

FIG. 5 illustrates a time delay between a generated read command from a master device and response signals for the bus arrangement 100 of FIG. 3.

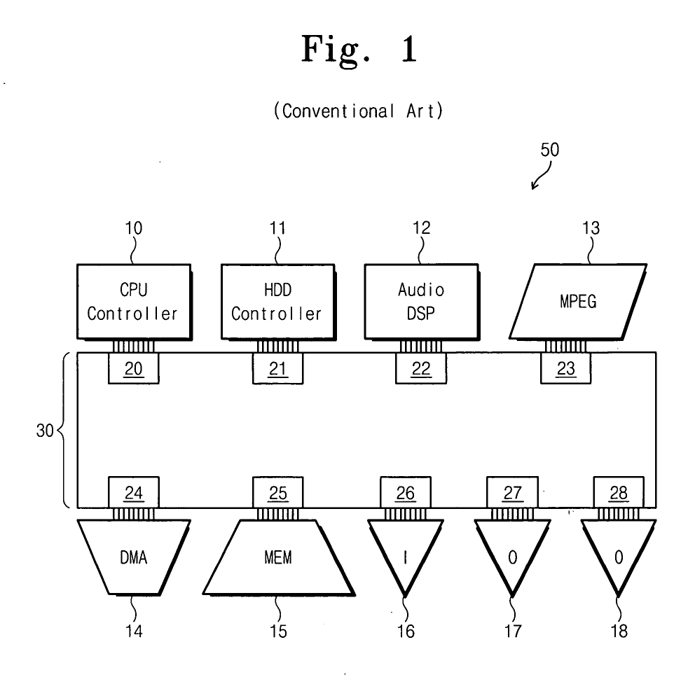

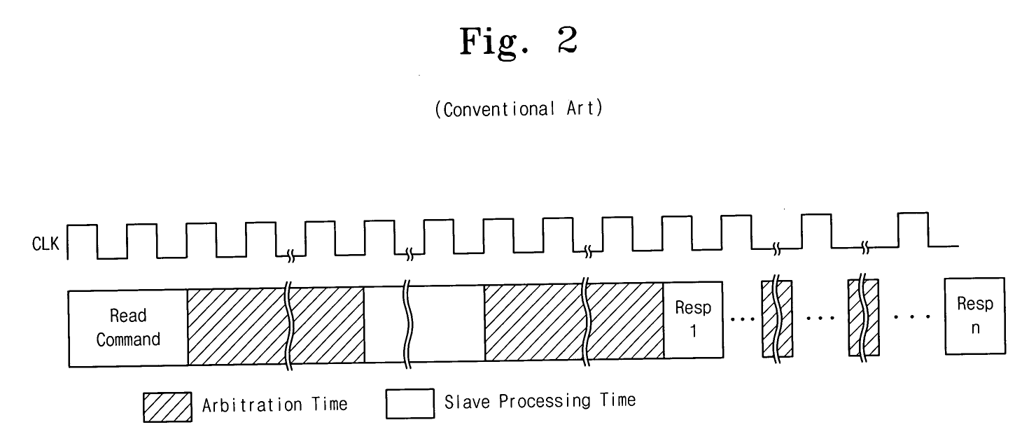

Referring again to FIGS. 1 and 2, arbitration delay may occur in conventional methods in the timing diagram of FIG. 2 since the response signal is sent through the network 30 of FIG. 1.

In another exemplary embodiment of the present invention, referring to FIG. 5, the arbitration delay may be reduced by sending the response signal from a memory to a device (i.e., master device, slave device, etc. . . . ) requesting data by sending the response signal through a bus not included within a network (e.g., network 120).

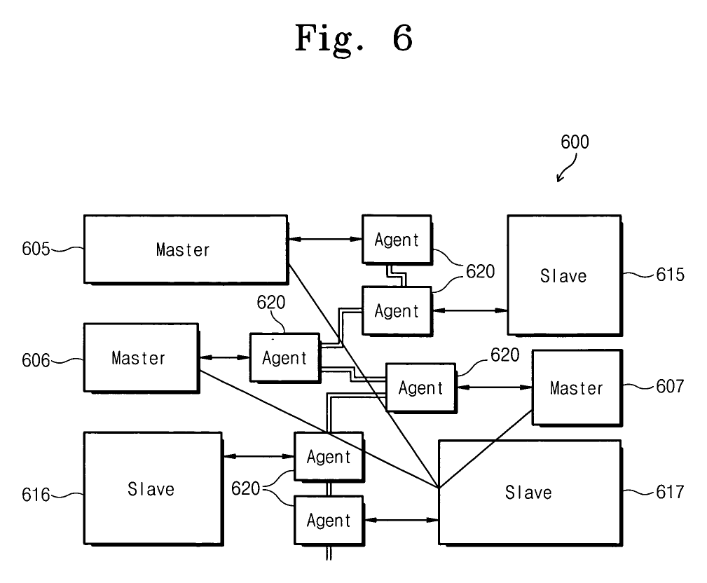

FIG. 6 illustrates a bus arrangement 600 according to another exemplary embodiment of the present invention.

In another exemplary embodiment of the present invention, the bus arrangement 600 may include a ring-type structure and may allocate resources (i.e., bandwidth) and may increase routing efficiency. The bus arrangement 600 may include master devices 605/606/607, slave devices 615/616/617 and/or agents 620.

In another exemplary embodiment of the present invention, referring to FIG. 6, the response delay time may be reduced by directly connecting the master devices 605/606/607 (e.g., CPU controllers) and the slave device 617 (e.g., a memory device).

In another exemplary embodiment of the present invention referring to FIGS. 3 and 4, the response decoder 140 may transmit a response signal and read data to at least one of the master devices 110/111/112 based on information received from the slave device 132.

In another exemplary embodiment of the present invention, the response decoder 140 may include a multiplexer and/or any other well known selection circuit.

In another exemplary embodiment of the present invention, bit widths of the buses 150/151/152 connecting the master devices 110/111/112 and the response decoder 140 may be adjusted based on a system characteristic (e.g., a size of the response data, a desired bandwidth, etc. . . . ).

In another exemplary embodiment of the present invention, communication over a network (e.g., a SB μ Network) may include a reduced delay time between a read command and a receipt of read data of a master device. Further, the network may include a micro-network (e.g., a SB μ micro-network).

The exemplary embodiments of the present invention being thus described, it will be obvious that the same may be varied in many ways. For example, while above-described slave devices may include memory devices, it is understood that other exemplary embodiments of the present invention may include any well-known slave device (e.g., DMA, etc. . . . ). Further, the above-described exemplary embodiments include three master devices, three slave devices, and a given number of agents. However, it is understood that any number of master devices, slave devices, and/or agents may be included in an exemplary bus arrangement. Further, while above-described bus protocols include OCP, any type of bus protocol (e.g., OCP, AMBA, etc . . . ) may be used. Further, while above-described networks may include SB μ networks, any type of well-known network may be included within any of the exemplary embodiments of the present invention.

Such variations are not to be regarded as departure from the spirit and scope of the example embodiments of the present invention, and all such modifications as would be obvious to one skilled in the art are intended to be included within the scope of the following claims.

1. A bus arrangement, comprising:
a bus network connecting a master device and a slave device; and
a response decoder receiving a response signal from the slave device, the response signal received on a first bus not included within the bus network.

2. The bus arrangement of claim 1, wherein the bus network is a Silicon Backplane (SB) μ Network.

3. The bus arrangement of claim 1, wherein the response decoder transmits the response signal to the master device.

4. The bus arrangement of claim 3, wherein the master device and the response decoder are connected via a second bus, the second bus not including a device connected between the master device and the response decoder.

5. The bus arrangement of claim 4, wherein the second bus is not included within the bus network.

6. The bus arrangement of claim 1, wherein the slave device includes a memory device.

7. A bus arrangement, comprising:
a bus network connecting a plurality of master devices and a plurality of slave devices;
a plurality of buses connecting a response decoder and the plurality of master devices, the plurality of buses not included within the bus network, the response decoder receiving a response signal from at least one of the plurality of slave devices and transmitting the response signal to at least one of the plurality of master devices.

8. The bus arrangement of claim 7, wherein the response signal includes destination information.

9. The bus arrangement of claim 8, wherein the at least one of the plurality of master devices is associated with the destination information.

10. The bus arrangement of claim 7, wherein the bus network is a Silicon Backplane (SB) μ Network.

11. The bus arrangement of claim 7, wherein the at least one of the plurality of slave devices includes a memory device.

12. The bus arrangement of claim 11, wherein the response signal includes data from the memory device.

13. A method of reading data, comprising:
generating a read command at a master device;
converting the read command to a write command;
transmitting the converted write command to a slave device through a bus network; and
transmitting data from the slave device in response to the write command to the master device through a bus not included within the bus network.

14. A bus arrangement, comprising:
a slave device and a master device connected through a bus network; and
a bus connecting the slave device and the master device, the bus not included within the bus network.

15. A method of reading data, comprising:
generating a read command at a first device; and
converting the read command into a write command.

16. The method of claim 15, further comprising:
transmitting the write command to a second device.

17. The method of claim 16, further comprising:
converting the write command into the read command at the second device.

18. The method of claim 17, further comprising:
executing the read command.

19. The method of claim 18, further comprising:
transmitting data to the first device.

20. A method of data transfer, comprising:
receiving a write command through a bus network; and
performing a read operation in response to the write command.

21. The method of claim 20, further comprising:
transmitting data in response to the read operation through a bus, the bus not included within the bus network.

22. A method of data transfer, comprising:
transmitting a write command through a bus network; and
receiving data in response to the write command through a bus, the bus not included within the bus network.

23. A master device, comprising:
a first connection to a slave device through a bus network; and
a second connection to the slave device, the second connection not included within the bus network.

24. A slave device, comprising:
a first connection to a master device through a bus network; and
a second connection to the master device, the second connection not included within the bus network.

25. A bus arrangement for performing the method of claim 13.

26. A bus arrangement for performing the method of claim 15.

27. A slave device for performing the method of claim 20.

28. A master device for performing the method of claim 22.
